(19) United States
(12) Patent Application Publication
(10) Pub. No.: US 2014/0238725 A1
(43) Pub. Date: Aug. 28, 2014

(54) METHOD OF FLATTENING SURFACE OF CONDUCTIVE STRUCTURE AND CONDUCTIVE STRUCTURE WITH FLATTENED SURFACE

(71) Applicant: INDUSTRIAL TECHNOLOGY RESEARCH INSTITUTE, (US)

(72) Inventors: Erh-Hao Chen, Changhua County (TW); Cha-Hsin Lin, Miaoli County (TW); Tzu-Kun Ku, Hsinchu City (TW)

(73) Assignee: INDUSTRIAL TECHNOLOGY RESEARCH INSTITUTE, Hsinchu (TW)

(21) Appl. No.: 13/778,132

(22) Filed: Feb. 27, 2013

(30) Foreign Application Priority Data
Feb. 25, 2013 (TW) 102106543

(51) Int. Cl. H05K 1/02; H05K 3/26

(52) U.S. Cl. CPC H05K 1/0296; H05K 3/26
USPC 174/251; 427/58; 216/16

(57) ABSTRACT

A method of flattening surface of conductive structure including a substrate, a dielectric layer on the substrate, and a conductive line formed in the dielectric layer is provided. A surface of the conductive line has a recess. A cover layer is formed on the substrate. A mechanical polishing process is performed to remove a portion of the cover layer. A remaining cover layer fills and levels the recess.

### CROSS-REFERENCE TO RELATED APPLICATION

This application claims the priority benefit of Taiwan application serial no. 102106543, filed on Feb. 25, 2013. The entirety of the above-mentioned patent application is hereby incorporated by reference herein and made a part of this specification.

### TECHNICAL FIELD

The disclosure relates to a method of flattening a surface of a conductive structure and a conductive structure with a flattened surface.

### BACKGROUND

With the decrease in chip size and the increasing demand for alignment accuracy, wafer-to-wafer bonding is becoming mainstream, and may replace chip-to-chip or chip-to-wafer bonding to reduce costs and improve yield. However, a dishing effect is occurred when a conductive line on a wafer is polished by a chemical mechanical polishing process. As a result, the yield of wafer-to-wafer bonding is decreased and the conductive line bonding the wafers above and below may not conduct properly.

### SUMMARY

An embodiment of the disclosure provides a method of flattening a surface of a conductive structure. The method includes providing a substrate, wherein a dielectric layer is on the substrate, and a conductive line is in the dielectric layer. The surface of the conductive line has a recess. A first cover layer is formed on the substrate. A mechanical polishing process is performed to remove a portion of the first cover layer. The remaining first cover layer fills and levels the recess.

An embodiment of the disclosure provides another method of flattening a surface of a conductive structure. The method includes providing a substrate, wherein a dielectric layer is formed on the substrate, and a conductive line is formed in the dielectric layer. The surface of the conductive line has a recess. The dielectric layer is etched back such that a portion of the sidewall of the conductive line is exposed. A mechanical polishing process is performed to remove the exposed conductive line such that the conductive line has a flattened surface.

An embodiment of the disclosure provides a conductive structure with a flattened surface. The conductive structure includes a dielectric layer, a conductive line, and a first cover layer. The dielectric layer is located on the substrate. The conductive line is located in the dielectric layer, and a surface of the conductive line has at least one recess. The first cover layer is located on the conductive line and at least fills and levels the recess.

An embodiment of the disclosure provides another conductive structure with a flattened surface. The conductive structure includes a dielectric layer, a cover layer, and a conductive line. The dielectric layer is located on the substrate. The cover layer is located on the dielectric layer. The conductive line is located in the cover layer and the dielectric layer and has a flat surface.

An embodiment of the disclosure provides another conductive structure with a flattened surface. The conductive structure includes a dielectric layer and a conductive line. The dielectric layer is located on the substrate. The conductive line is located in the dielectric layer and has a linewidth of 0.01 μm to 5 mm. The conductive line has a flat surface.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A to 1C are schematic cross-sectional views illustrating the steps of a method of flattening a surface of a conductive structure according to the first embodiment of the disclosure.

FIG. 2A to 2C are schematic cross-sectional views illustrating the steps of a method of flattening a surface of a conductive structure according to the second embodiment of the disclosure.

FIG. 3A to 3D are schematic cross-sectional views illustrating the steps of a method of flattening a surface of a conductive structure according to the third embodiment of the disclosure.

FIG. 4A to 4D are schematic cross-sectional views illustrating the steps of a method of flattening a surface of a conductive structure according to the fourth embodiment of the disclosure.

FIG. 5A to 5D are schematic cross-sectional views illustrating the steps of a method of flattening a surface of a conductive structure according to the fifth embodiment of the disclosure.

FIG. 6A to 6E are schematic cross-sectional views illustrating the steps of a method of flattening a surface of a conductive structure according to the sixth embodiment of the disclosure.

FIG. 7A to 7C are schematic cross-sectional views illustrating the steps of a method of flattening a surface of a conductive structure according to the seventh embodiment of the disclosure.

### DETAILED DESCRIPTION OF DISCLOSED EMBODIMENTS

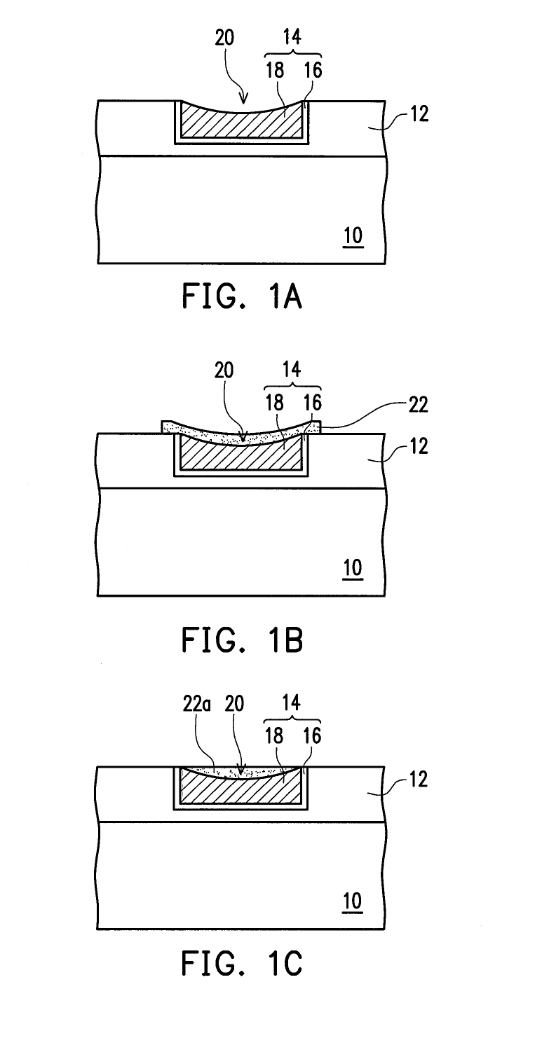

FIG. 1A to 1C are schematic cross-sectional views illustrating the steps of a method of flattening a surface of a conductive structure according to the first embodiment of the disclosure.

Referring to FIG. 1A, a substrate 10 is provided. A dielectric layer 12 is formed on the substrate 10. A conductive line 14 is formed in the dielectric layer 12. An integrated circuit device or a metal interconnection etc. may already have formed between the substrate 10 and the dielectric layer 12. The material of the dielectric layer 12 is, for example, silicon oxide or a low dielectric constant material with a dielectric constant of less than 4. The conductive line 14 is, for example, a pad above a metal interconnection. The linewidth of the conductive line 14 may be 0.01 μm to 5 mm. The conductive line 14 may include a barrier layer 16 in addition to a conductive layer 18. The barrier layer 16 is between the conductive layer 18 and the dielectric layer 12. The material of the barrier layer 16 is, for example, titanium, titanium nitride, tantalum, tantalum nitride, ruthenium, or cobalt tungsten phosphorous etc., or a stacked layer of the combination thereof. The conductive layer 18 is, for example, copper, aluminum, or a copper aluminum alloy etc. The surface of the conductive line 14 has at least one recess 20. The recess 20 may be caused by a chemical mechanical planarization process or other possible factors.

Next, referring to FIG. 1B, a cover layer 22 is formed on the substrate 10. The cover layer 22 may be a conductor, and the material of the cover layer 22 may be a metal or a metal alloy such as aluminum, tin, gold, or silver etc. The cover layer 22 may be formed by electroless plating, a chemical vapor deposition method, or a physical vapor deposition method, but is not limited thereto. The cover layer 22 needs to be of enough thickness to completely fill the recess 20.

Then, referring to FIG. 1C, a mechanical polishing process is performed to remove a portion of the cover layer 22. A remaining cover layer 22a fills and levels the recess 20 of the conductive line 14. The mechanical polishing process may be completed through any known mechanical polishing method, such as the use of a diamond head polishing machine. The diamond head polishing machine performs the polishing action by applying a mechanical force to the surface of a material such as a metal, a photoresist material, or a polymer to achieve a flattening effect. The diamond head polishing machine uses a hard diamond as the knife head for polishing along a horizontal plane, and, for example, performs the polishing operation by applying a mechanical force in a clockwise rotation to flatten a surface.

Referring to FIG. 1C, the flattened conductive structure of the present embodiment includes the substrate 10, dielectric layer 12, conductive line 14, and cover layer 22a. The dielectric layer 12 is located on the substrate 10. The conductive line 14 is located in the dielectric layer 12, and the conductive line 14 has at least one recess 20. The cover layer 22a is located on the conductive line 14 and at least needs to fill and level the recess 20. The dielectric layer 12, cover layer 22a, and conductive line 14 has a flat surface.

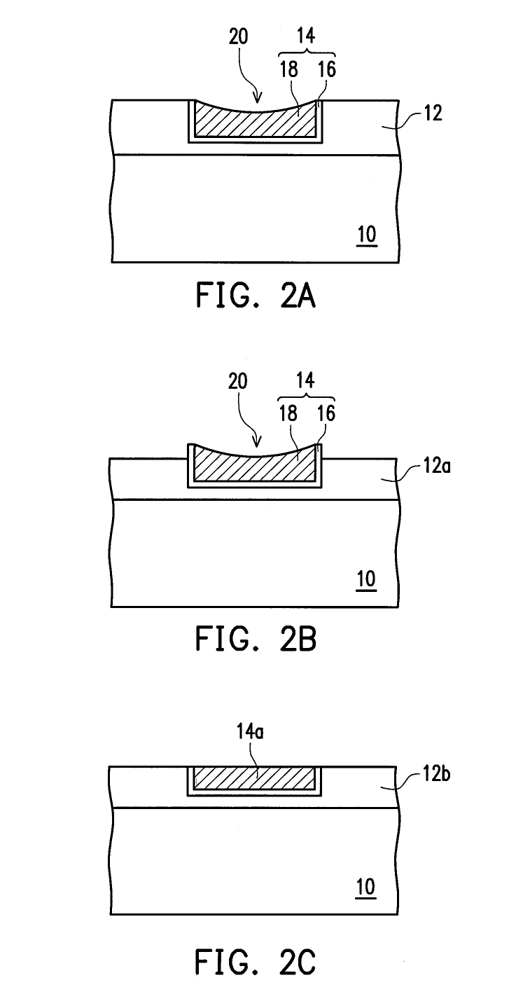

FIG. 2A to 2C are schematic cross-sectional views illustrating the steps of a method of flattening a surface of a conductive structure according to the second embodiment of the disclosure.

Referring to FIG. 2A, as described in the first embodiment, the dielectric layer 12 is formed on the substrate. The conductive line 14 is already formed in the dielectric layer 12. The linewidth of the conductive line 14 may be 0.01 μm to 5 mm The conductive line 14 may include the barrier layer 16 in addition to the conductive layer 18. The surface of the conductive line 14 has at least one recess 20.

Referring to FIG. 2B, the dielectric layer 12 is etched back to leave a dielectric layer 12a such that a portion of the sidewall of the conductive line 14 is exposed. An isotropic etching method may be used to etch back the dielectric layer 12, such as using a wet etching method and a diluted hydrofluoric acid as the etchant.

Referring to FIG. 2C, a mechanical polishing process is performed to remove a portion of the exposed conductive line 14. Each of a remaining conductive line 14a and dielectric layer 12b have a flat surface. The mechanical polishing process may be completed through any known mechanical polishing method, such as the use of a diamond head polishing machine.

Referring to FIG. 2C, the flattened conductive structure of the present embodiment includes the substrate 10, the dielectric layer 12b, and the conductive line 14a. The dielectric layer 12b is located on the substrate 10. The conductive line 14a is located in the dielectric layer 12b and the linewidth of the conductive line 14a may be 0.01 μm to 5 mm. The conductive line 14a has a flat surface.

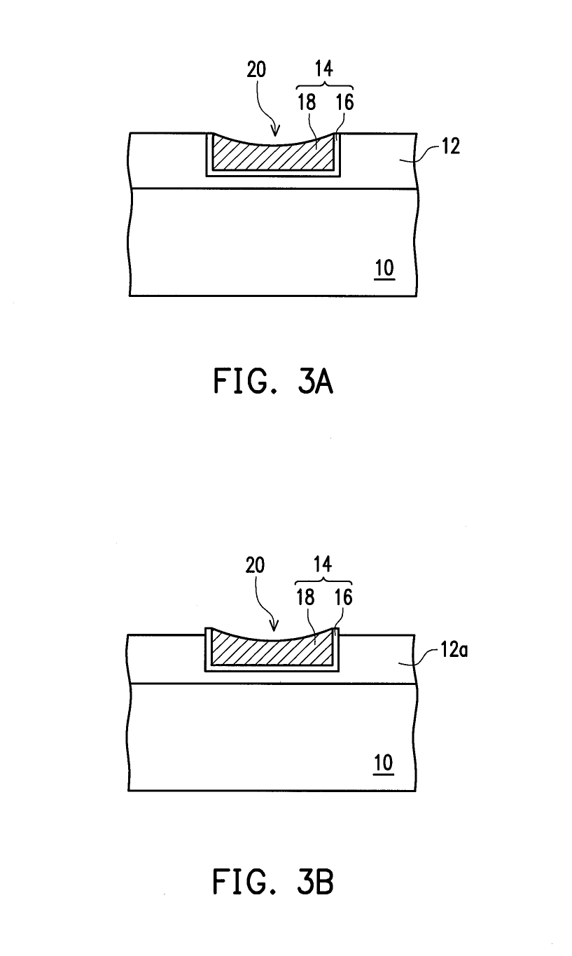

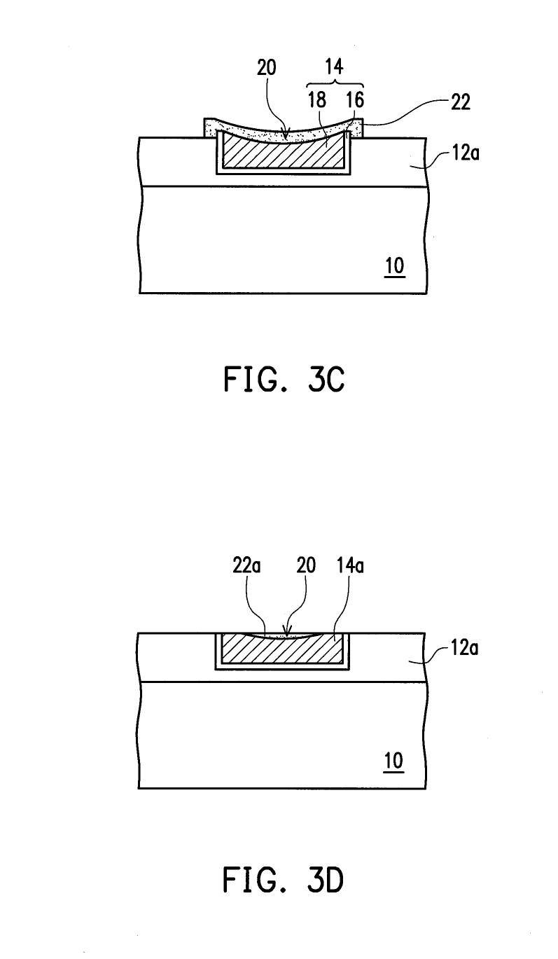

FIG. 3A to 3D are schematic cross-sectional views illustrating the steps of a method of flattening a surface of a conductive structure according to the third embodiment of the disclosure.

Referring to FIG. 3A, as described in the first embodiment, the dielectric layer 12 is formed on the substrate 10. The conductive line 14 is already formed in the dielectric layer 12. The linewidth of the conductive line 14 may be 0.01 μm to 5 mm. The conductive line 14 may include the barrier layer 16 in addition to the conductive layer 18. The surface of the conductive line 14 has at least one recess 20.

Referring to FIG. 3B, as described in the second embodiment, the dielectric layer 12 is etched back to leave the dielectric layer 12a such that a portion of the sidewall of the conductive line 14 is exposed.

Then, referring to FIG. 3C, the cover layer 22 is formed on the substrate 10 to cover an exposed sidewall and the recess 20 of the conductive line 14. The material, thickness, and formation method of the cover layer 22 may be as described in the first embodiment and are not repeated herein.

Then, referring to FIG. 3D, a mechanical polishing process is performed to remove a portion of the cover layer 22 and a portion of the conductive line 14. The remaining cover layer 22a fills and levels the at least one recess 20 of the conductive line 14a. The mechanical polishing process may be completed through any known mechanical polishing method, such as the use of a diamond head polishing machine.

Referring to FIG. 3D, the flattened conductive structure of the present embodiment includes the substrate 10, the dielectric layer 12a, the conductive line 14a, and the cover layer 22a. The dielectric layer 12a is located on the substrate 10. The conductive line 14a is located in the dielectric layer 12a, and the conductive line 14a has at least one recess 20. The cover layer 22a is located on the conductive line 14a and at least needs to fill and level the recess 20. The dielectric layer 12a, cover layer 22a, and conductive line 14a has a flat surface.

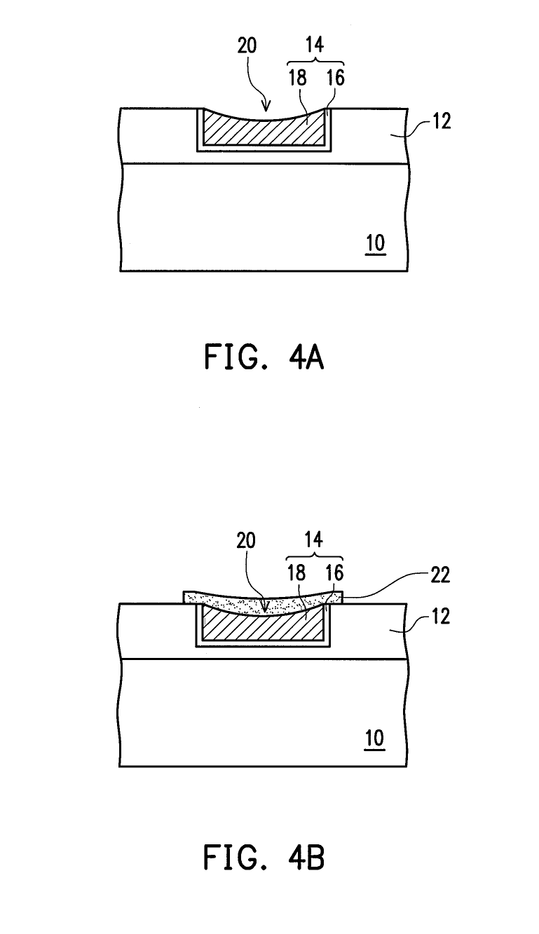

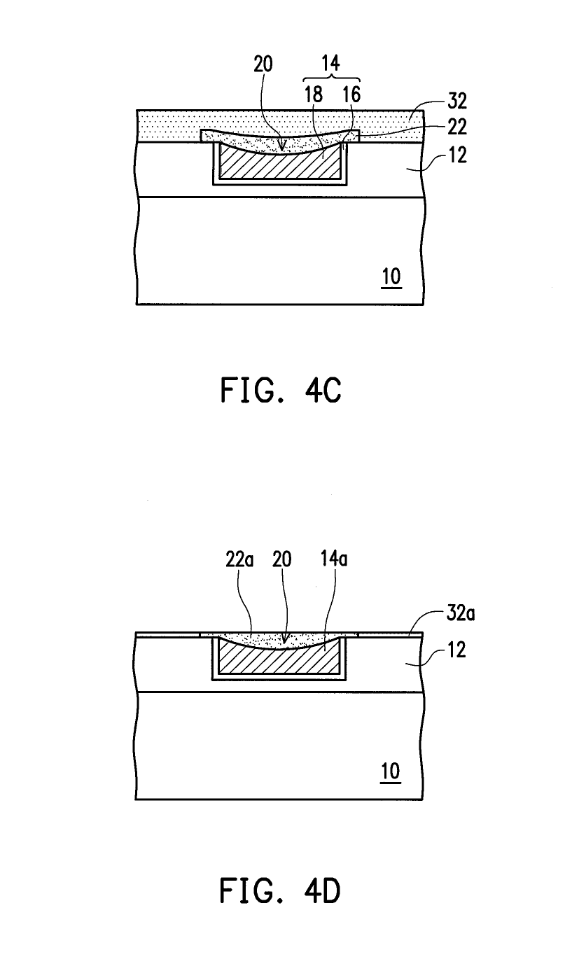

FIG. 4A to 4D are schematic cross-sectional views illustrating the steps of a method of flattening a surface of a conductive structure according to the fourth embodiment of the disclosure.

Referring to FIG. 4A, as described in the first embodiment, the dielectric layer 12 is already formed on the substrate 10. The conductive line 14 is already formed in the dielectric layer 12. The linewidth of the conductive line 14 may be 0.01 μm to 5 mm. The conductive line 14 may include the barrier layer 16 in addition to the conductive layer 18. The surface of the conductive line 14 has at least one recess 20.

Then, referring to FIG. 4B, the cover layer 22 is formed on the substrate 10 according to the method of the first embodiment.

Then, referring to FIG. 4C, another cover layer 32 is formed on the substrate 10 to cover the cover layer 22 and the dielectric layer 12. The cover layer 32 may be a polymer such as benzocyclobutene (BCB) or polyimide (PI). The cover layer 32 may be formed by a coating or deposition method. The coating method is, for example, a spin coating method. The deposition method is, for example, chemical vapor deposition (CVD).

Then, referring to FIG. 4D, a mechanical polishing process is performed to remove a portion of the cover layer 32 and a portion of the cover layer 22. In an embodiment, the remaining cover layer 22a fills and levels the recess 20 of the conductive line 14, a portion of a cover layer 32a remains on the surface of the dielectric layer 12, and each of the cover layer 22a, conductive line 14a, and cover layer 32a have a flat surface. In another embodiment, the remaining cover layer 22a fills and levels the recess 20 of the conductive line 14 to expose the surface of the dielectric layer 12. The mechanical polishing process may be completed through any known mechanical polishing method, such as the use of a diamond head polishing machine.

Referring to FIG. 4D, the flattened conductive structure of the present embodiment includes the substrate 10, dielectric layer 12, conductive line 14a, cover layer 32a, and cover layer 22a. The dielectric layer 12 is located on the substrate 10. The cover layer 32a is located on the dielectric layer 12. The conductive line 14a is located in the dielectric layer 12, and the conductive line 14a has at least one recess 20. The cover layer 22a is located on the conductive line 14a and at least needs to fill and level the recess 20. The dielectric layer 12, cover layer 22a, cover layer 32a, and conductive line 14a has a flat surface. In another embodiment, the cover layer 32a is polished to expose the dielectric layer 12. In other words, each of the dielectric layer 12, cover layer 22a, and conductive line 14a have a flat surface.

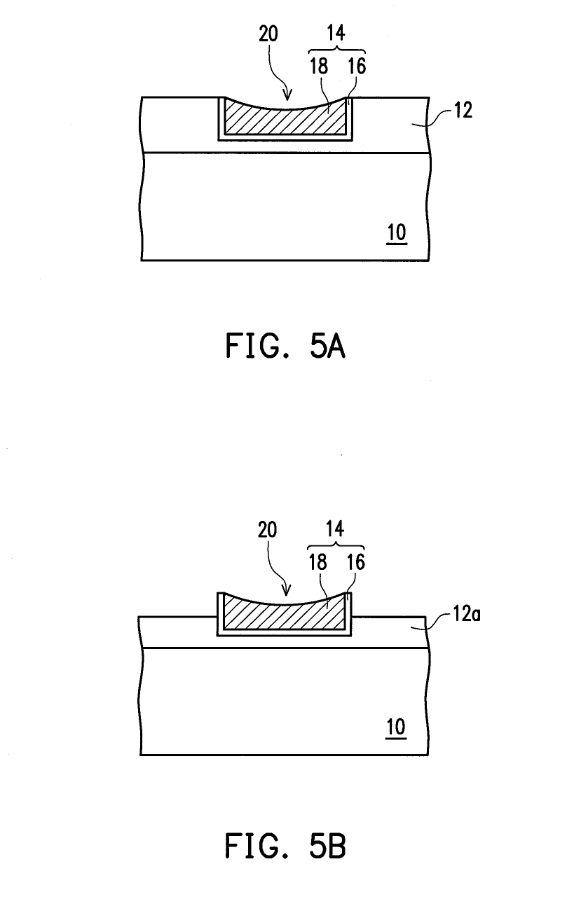

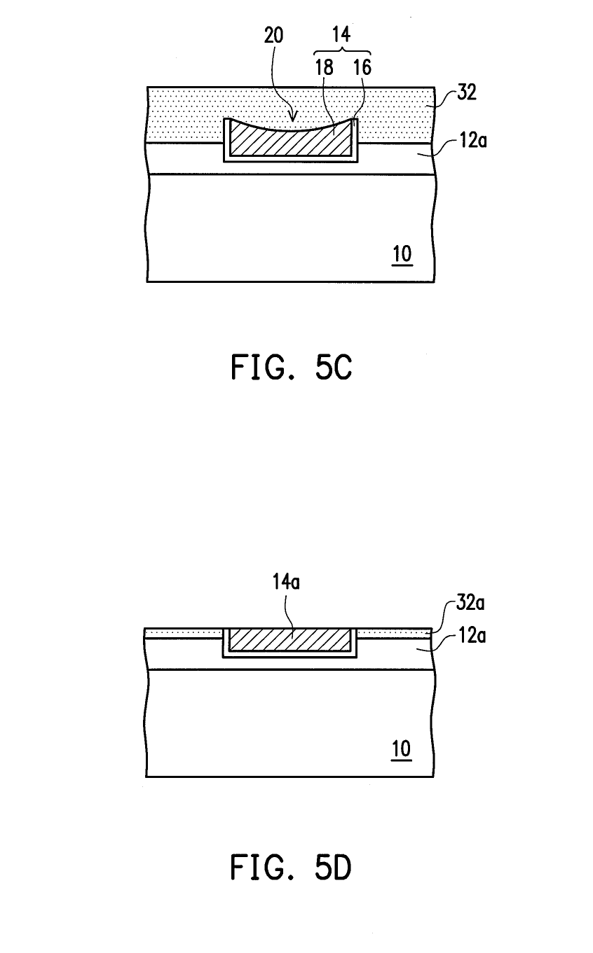

FIG. 5A to 5D are schematic cross-sectional views illustrating the steps of a method of flattening a surface of a conductive structure according to the fifth embodiment of the disclosure.

Referring to FIG. 5A, as described in the first embodiment, the dielectric layer 12 is already formed on the substrate 10. The conductive line 14 is already formed in the dielectric layer 12. The linewidth of the conductive line 14 may be 0.01 μm to 5 mm. The conductive line 14 may include the barrier layer 16 in addition to the conductive layer 18. The surface of the conductive line 14 has at least one recess 20.

Referring to FIG. 5B, as described in the second embodiment, the dielectric layer 12 is etched back to leave the dielectric layer 12a such that a portion of the sidewall of the conductive line 14 is exposed.

Referring to FIG. 5C, the cover layer 32 is formed on the substrate 10 to cover the surface of the dielectric layer 12a and the at least one recess 20 of the conductive line 14. The material and formation method of the cover layer 32 may be as described in the fourth embodiment and are not repeated herein.

Then, referring to FIG. 5D, a mechanical polishing process is performed to remove a portion of the cover layer 32. The remaining cover layer 32a and conductive line 14a has a flat surface. The mechanical polishing process may be completed through any known mechanical polishing method, such as the use of a diamond head polishing machine.

Referring to FIG. 5D, the flattened conductive structure of the present embodiment includes the substrate 10, the dielectric layer 12a, the conductive line 14a, and the cover layer 32a. The dielectric layer 12a is located on the substrate 10. The cover layer 32a is located on the dielectric layer 12a. The conductive line 14a is located in the dielectric layer 12a and the cover layer 32a. The cover layer 32a and conductive line 14a has a flat surface.

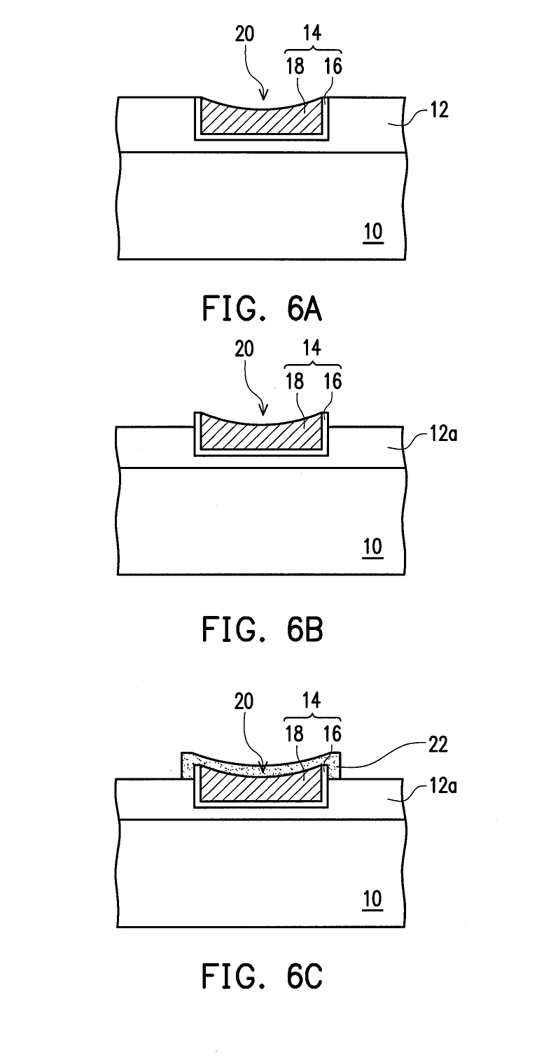

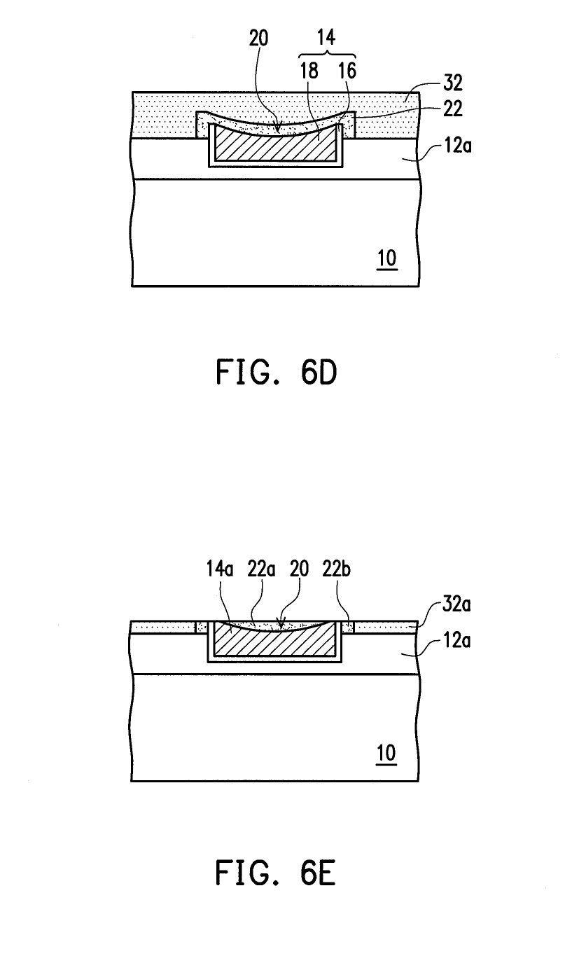

FIG. 6A to 6E are schematic cross-sectional views illustrating the steps of a method of flattening a surface of a conductive structure according to the sixth embodiment of the disclosure.

Referring to FIG. 6A, as described in the first embodiment, the dielectric layer 12 is already formed on the substrate 10. The conductive line 14 is already formed in the dielectric layer 12. The linewidth of the conductive line 14 may be 0.01 μm to 5 mm. The conductive line 14 may include the barrier layer 16 in addition to the conductive layer 18. The surface of the conductive line 14 has at least one recess 20.

Referring to FIG. 6B, as described in the second embodiment, the dielectric layer 12 is etched back to leave the dielectric layer 12a such that a portion of the sidewall of the conductive line 14 is exposed.

Referring to FIG. 6C, the cover layer 22 is formed on the substrate 10 to cover the exposed sidewall of the conductive line 14 and the at least one recess 20. The material, thickness, and formation method of the cover layer 22 may be as described in the first embodiment and are not repeated herein.

Referring to FIG. 6D, the cover layer 32 is formed on the substrate 10 to cover the surface of each of the cover layer 22 and dielectric layer 12a. The material and formation method of the cover layer 32 may be as described in the fourth embodiment and are not repeated herein.

Then, referring to FIG. 6E, a mechanical polishing process is performed to remove a portion of the cover layer 32 and a portion of the cover layer 22. The remaining conductive line 14a, cover layer 22a, cover layer 22b, and cover layer 32a has a flat surface. The mechanical polishing process may be completed through any known mechanical polishing method, such as the use of a diamond head polishing machine.

Referring to FIG. 6E, the flattened conductive structure of the present embodiment includes the substrate 10, dielectric layer 12a, cover layer 32a, conductive line 14a, cover layer 22a, and cover layer 22b. The dielectric layer 12a is located on the substrate 10. The cover layer 32a and the cover layer 22b are located on the dielectric layer 12a. The conductive line 14a is located in the dielectric layer 12a and the cover layer 22b, and the conductive line 14a has at least one recess 20. The cover layer 22a is located on the conductive line 14a and at least needs to fill and level the recess 20. The conductive line 14a, cover layer 22a, cover layer 22b, and cover layer 32a have a flat surface.

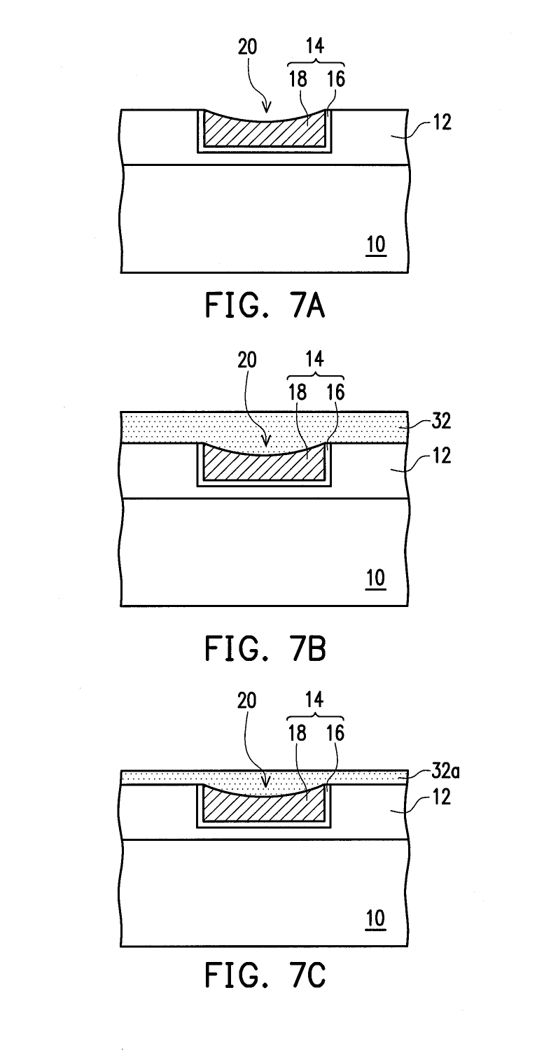

FIG. 7A to 7C are schematic cross-sectional views illustrating the steps of a method of flattening a surface of a conductive structure according to the seventh embodiment of the disclosure.

Referring to FIG. 7A, as described in the first embodiment, the dielectric layer 12 is already formed on the substrate 10. The conductive line 14 is already formed in the dielectric layer 12. The linewidth of the conductive line 14 may be 0.01 μm to 5 mm. The conductive line 14 may include the barrier layer 16 in addition to the conductive layer 18. The surface of the conductive line 14 has at least one recess 20.

Referring to FIG. 7B, the cover layer 32 is formed on the substrate 10 to cover the surface of the dielectric layer 12 and completely fill the recess 20. The material and formation method of the cover layer 32 may be as described in the fourth embodiment and are not repeated herein.

Then, referring to FIG. 7C, a mechanical polishing process is performed to remove a portion of the cover layer 32. The remaining cover layer 32a has a flat surface. The mechanical polishing process may be completed through any known mechanical polishing method, such as the use of a diamond head polishing machine.

Referring to FIG. 7C, the flattened conductive structure of the present embodiment includes the substrate 10, dielectric layer 12, conductive line 14, and cover layer 32a. The dielectric layer 12 is located on the substrate 10. The conductive line 14 is located in the dielectric layer 12, and the conductive line 14 has at least one recess 20. The cover layer 32a is located on the dielectric layer 12 and at least needs to fill and level the recess 20. The cover layer 32a has a flat surface.

The flattened conductive structure of the first to seventh embodiments may, in conjunction with another flattened conductive structure, stack wafers in a face-to-face manner and directly bonding the conductive lines without the use of bumps. However, in the seventh embodiment, after the wafers are bonded in a stack in a face-to-face manner, although bumps are not needed to electrically connect the conductive line of each of two flattened conductive structures, a through silicon via (TSV) method is still needed to electrically connect the conductive line of each of two flattened conductive structures.

Based on the above, in an embodiment of the disclosure, by the formation of the cover layer and the mechanical polishing method, in conjunction with the etching back of the dielectric layer, the conductive structure formed may have a flattened surface. As a result, during the bonding of the wafer-to-wafer stack, the contact area of the conductive line may be increased and the bonding strength of the wafer interface may be improved. Therefore, subsequent processes may be facilitated, the conduction of the conductive line joining the wafers above and below is ensured, and the yield of wafer-to-wafer bonding is improved.

Although the disclosure has been described with reference to the above embodiments, it will be apparent to one of the ordinary skill in the art that modifications to the described embodiments may be made without departing from the spirit of the disclosure. Accordingly, the scope of the disclosure is defined by the attached claims not by the above detailed descriptions.

What is claimed is:

1. A method of flattening a surface of a conductive structure, comprising:
providing a substrate, wherein a dielectric layer is formed on the substrate, a conductive line is formed in the dielectric layer, and a surface of the conductive line has at least one recess;
forming a first cover layer on the substrate; and
performing a mechanical polishing process to remove a portion of the first cover layer such that a remaining first cover layer fills and levels the recess of the conductive line.

2. The method of claim 1, wherein the first cover layer is a conductor, and after the mechanical polishing process, a surface of the dielectric layer is exposed.

3. The method of claim 1, wherein the first cover layer is a conductor, and further comprising, before forming the first cover layer on the substrate, etching back the dielectric layer such that a portion of a sidewall of the conductive line is exposed.

4. The method of claim 3, further comprising, before performing the mechanical polishing process, forming a second cover layer on a surface of the first cover layer, wherein the second cover layer is a polymer.

5. The method of claim 1, wherein the first cover layer is a conductor, and further comprising, before performing the mechanical polishing process, forming a second cover layer on a surface of the first cover layer, wherein the second cover layer is a polymer.

6. The method of claim 1, wherein the first cover layer is a polymer, and after the mechanical polishing process, the first cover layer covers the recess of the conductive line and a surface of the dielectric layer.

7. The method of claim 1, wherein the first cover layer is a polymer, and further comprising, before forming the first cover layer on the substrate, etching back the dielectric layer such that a portion of a sidewall of the conductive line is exposed, and after the mechanical polishing process, the conductive line has a flattened surface and the first cover layer covers the surface of the dielectric layer.

8. A method of flattening a surface of a conductive structure, comprising:
providing a substrate, wherein a dielectric layer is on the substrate, a conductive line is formed in the dielectric layer, and a surface of the conductive line has at least one recess;
etching back the dielectric layer such that a portion of a sidewall of the conductive line is exposed; and
performing a mechanical polishing process to remove the exposed conductive line such that the conductive line has a flattened surface.

9. A conductive structure with a flattened surface, comprising:
a dielectric layer located on a substrate;
a conductive line located in the dielectric layer, wherein a surface of the conductive line has at least one recess; and
a first cover layer located on the conductive line and at least fills and levels the recess.

10. The conductive structure of claim 9, wherein the first cover layer is a conductor.

11. The conductive structure of claim 9, wherein a sidewall of the conductive line protrudes beyond the dielectric layer, the first cover layer further covers the sidewall of the conductive line and further comprises a second cover layer covering the dielectric layer, wherein the second cover layer comprises a polymer.

12. The conductive structure of claim 9, wherein the first cover layer is a polymer, and the first cover layer further covers the dielectric layer and has a flat surface.

13. A conductive structure with a flattened surface, comprising:
a dielectric layer located on a substrate;
a cover layer located on the dielectric layer; and
a conductive line located in the cover layer and the dielectric layer, wherein the conductive line has a flat surface.

14. The conductive structure of claim 13, wherein a linewidth of the conductive line is 0.01 μm to 5 mm.

15. A conductive structure with a flattened surface, comprising:
a dielectric layer located on a substrate; and
a conductive line located in the dielectric layer, wherein a linewidth of the conductive line is 0.01 μm to 5 mm and the conductive line has a flat surface.
